(19) United States
(12) Patent Application Publication
(10) Pub. No.: US 2012/0146156 A1
(43) Pub. Date: Jun. 14, 2012

(54) SEMICONDUCTOR DEVICE AND METHOD FOR FABRICATING SAME

(75) Inventors: MASANORI SHIRAHAMA, Shiga (JP); YASUHIRO AGATA, Osaka (JP); TOSHIAKI KAWASAKI, Osaka (JP); YUICHI HIROFUJI, Osaka (JP); TAKAYUKI YAMADA, Toyama (JP)

(73) Assignee: PANASONIC CORPORATION, Osaka (JP)

(21) Appl. No.: 13/396,892

(22) Filed: Feb. 15, 2012

Related U.S. Application Data
(63) Continuation of application No. PCT/JP2010/002307, filed on Mar. 30, 2010.

(30) Foreign Application Priority Data
Aug. 27, 2009 (JP) 2009-196325

(51) Int. Cl. H01L 27/06; H01L 21/8234

(52) U.S. Cl. 257/379; 438/238; 257/E27.014; 257/E21.616

(57) ABSTRACT

A semiconductor device includes an MIS transistor and an electric fuse. The MIS transistor includes a gate insulating film formed on the semiconductor substrate, and a gate electrode including a first polysilicon layer, a first silicide layer, and a first metal containing layer made of a metal or a conductive metallic compound. The electric fuse includes an insulating film formed on the semiconductor substrate, a second polysilicon layer formed over the insulating film, and a second silicide layer formed on the second polysilicon layer.

### CROSS-REFERENCE TO RELATED APPLICATIONS

This is a continuation of PCT International Application PCT/JP2010/002307 filed on Mar. 30, 2010, which claims priority to Japanese Patent Application No. 2009-196325 filed on Aug. 27, 2009. The disclosures of these applications including the specifications, the drawings, and the claims are hereby incorporated by reference in their entirety.

### BACKGROUND

The techniques described in the present specification relate to semiconductor devices having an electric fuse.

In recent years, higher-function and higher-performance devices have been developed. In addition, there is a strong demand for lower power consumption, such as longer operating time of portable digital devices. To achieve such high-performance and lower-power-consumption devices, leading-edge semiconductor devices, and patterns of semiconductor integrated circuits for realizing such the leading-edge semiconductor devices are miniaturized. This provides high integration and leads to higher function and lower power consumption. On the other hand, an increase in gate leakage current due to tunneling is a significant problem associated with a reduction in thicknesses of gate insulating films of transistors due to the miniaturization of the patterns of the semiconductor integrated circuits. Solutions for the increase in gate leakage current include forming an insulating film whose dielectric constant is high (i.e., a high-k gate insulating film) and a metal gate electrode on an oxide film. Dual metal gate transistors in which an n-channel transistor and a p-channel transistor are comprised of the combination of a high-k gate insulating film and a metal gate electrode have been actively developed in recent years (see, for example, Japanese Patent Publication No. 2007-194652).

In an element technology necessary for system development, that is, a large semiconductor integrated circuit (i.e., system LSI) on which a processor, a memory, a phase locked loop (PLL) circuit, an analog circuit etc. are provided, a fuse element (hereinafter referred to as “electric fuse”) having a multilayer structure of a polysilicon layer and a silicide layer has been widely used as a simple program element, such as a memory defect recovery circuit, a PLL circuit, and a circuit for tuning analog values.

Methods for cutting the electric fuse include applying a predetermined program potential to both ends of the electric fuse, thereby allowing a current to flow in a silicide layer, to make the silicide gather and increase the resistance of the electric fuse (see, for example, Japanese Patent Publication No. H11-512879 of PCT International Application).

### SUMMARY

Methods for reading from the electric fuse include directly detecting resistance values before and after the cutting of the electric fuse, and detecting by comparing the resistance of the electric fuse and the resistance of a reference resistance element which is separately provided and has an resistance value intermediate between the resistances before and after the cutting of the electric fuse. In either case, it is preferable that the ratio between the sheet resistance value of the silicide layer and the sheet resistance value of the polysilicon layer is high.

In the case of using the reference resistance element, the reading is conducted by determining whether the fuse is melted or not by using, for example, a differential amplifier circuit. However, if the patterns are further miniatulized and a metal gate electrode is formed, or if not the metal gate electrode, but a polysilicon film is formed to have a low sheet resistance, then the difference between the resistance values before and after the cutting of the electric fuse becomes much smaller than the difference in the conventional processes, due to the reduction in the sheet resistance value.

To detect the melting of the electric fuse in the differential amplifier circuit, it is necessary to increase a current so that the voltage deference ΔV between the state where the electric fuse is cut and the state where the electric fuse is not cut can be increased, or necessary to increase the accuracy of the differential amplifier circuit. However, if the current is increased, stress current may cause the melting of an electric fuse which is not supposed to be melted. Thus, the general chip size needs to be increased so that the accuracy of the differential amplifier circuit can be increased.

According to an example embodiment of the present invention, it is possible to provide an electric fuse which has a polysilicon layer and a silicide layer, and whose selectivity is stable even in finer patterns.

A semiconductor device according to an embodiment of the present invention includes an MIS transistor formed on a semiconductor substrate, and an electric fuse formed on the semiconductor substrate.

The MIS transistor includes: a gate insulating film formed on the semiconductor substrate; and a gate electrode including a first polysilicon layer formed above the gate insulating film, and a first silicide layer formed on the first polysilicon layer, and a first metal containing layer formed between the gate insulating film and the first polysilicon layer, and made of a metal or a conductive metallic compound. The electric fuse includes an insulating film formed on the semiconductor substrate, a second polysilicon layer formed over the insulating film, and a second silicide layer formed on the second polysilicon layer.

In this structure, if the second silicide layer of the electric fuse is melted, the resistance value can be significantly increased from before the melting. Therefore, even in a finer pattern, it is possible to easily detect whether the fuse is cut or not. Further, even in the case where a differential amplifier circuit is used for detection, there is no need to increase detection accuracy of the differential amplifier circuit.

The gate insulating of the MIS transistor may contain a high-k material.

In this structure, it is possible to reduce the occurrence of leakage current in the transistor even in a finer pattern.

A method for fabricating a semiconductor device according to an embodiment of the present invention includes: (a) forming a gate insulating film and a first polysilicon layer on a transistor formation area of a semiconductor substrate, and a first insulating film and a second polysilicon layer on an electric fuse formation area of the semiconductor substrate; (b) implanting an impurity ion in the first polysilicon layer and the transistor formation area of the semiconductor substrate, with the electric fuse formation area on which the second polysilicon layer has been formed covered with a mask; and (c) forming a first silicide layer on the first polysilicon layer, and a second silicide layer on the second polysilicon layer.

According to this method, the first polysilicon layer and the second polysilicon layer can be formed in the same process. Thus, the number of processes is not increased. Further, no impurity is implanted in the second polysilicon layer when an impurity is implanted in the transistor formation area. Thus, the sheet resistance of the second polysilicon layer can be higher than the sheet resistance of the first polysilicon layer. As a result, the resistance value of the electric fuse after melting can be significantly larger than the resistance value before melting.

According to a semiconductor device of an embodiment of the present invention, even if a fuse element has a metal gate structure, or if the resistance of a polysilicon layer is reduced due to effects of a metal layer in a leading process in which progress is being made for further miniaturization, it is possible to increase the resistance of a polysilicon portion of the fuse element. Thus, the resistance value of the electric fuse after melting can be significantly larger than the resistance value before melting.

### BRIEF DESCRIPTION OF THE DRAWINGS

FIG. 1 is a cross-sectional view of a semiconductor device having an electric fuse and a p-channel MIS transistor whose gate electrode has a metal gate structure.

FIG. 2 shows an example read circuit for an electric fuse.

FIGS. 3A-3C are cross-sectional views for showing a method for fabricating a semiconductor device according to embodiment.

FIGS. 4A-4D are cross-sectional views for showing a method for fabricating a semiconductor device according to embodiment.

FIG. 5 is a cross-sectional view of a semiconductor device according to the first variation of embodiment.

FIGS. 6A-6C are cross-sectional views for showing a method for fabricating a semiconductor device according to the first variation.

FIGS. 7A-7C are cross-sectional views for showing a method for fabricating a semiconductor device according to the first variation.

FIGS. 8A-8C are cross-sectional views for showing a method for fabricating a semiconductor device according to the first variation.

FIG. 9 is a cross-sectional view of a semiconductor device according to the second variation of embodiment.

FIG. 10 is an electric fuse viewed from above a substrate.

### DETAILED DESCRIPTION

### Embodiment

An electric fuse and a method for fabricating the electric fuse according to one embodiment of the present invention will be described below with reference to the drawings.

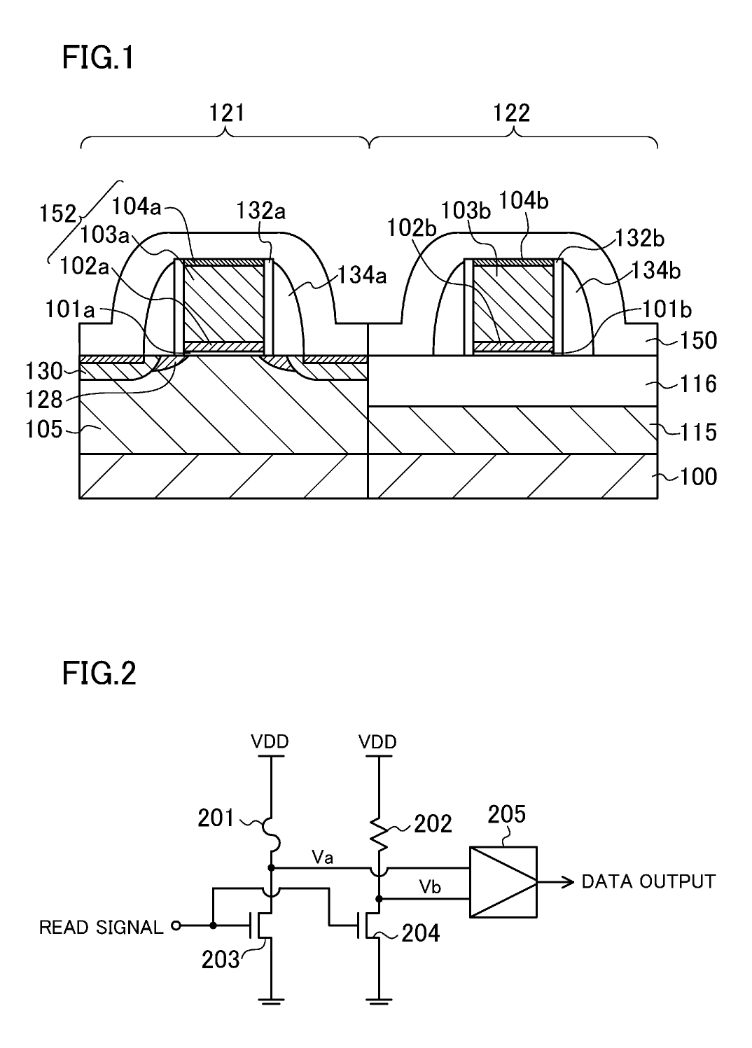

FIG. 1 is a cross-sectional view of a semiconductor device having an electric fuse and a p-channel MIS transistor whose gate electrode has a metal gate structure.

As shown in FIG. 1, a semiconductor substrate 100 includes a PMIS transistor formation area 121 and an electric fuse formation area 122. A p-channel MIS transistor is formed on the PMIS transistor formation area 121. An electric fuse is formed on the electric fuse formation area 122.

The p-channel MIS transistor includes: an n well 105 formed on the semiconductor substrate 100; a gate insulating film 101a formed on the n well 105; a metal layer (a first metal containing layer) 102a formed on the gate insulating film 101a and made, for example, of titanium nitride (TiN); a polysilicon layer 103a formed on the metal layer 102a; and a silicide layer 104a formed on the polysilicon layer 103a. The gate insulating film 101a contains a high-k material as represented by, for example, hafnium oxide, and may further contain silicon and nitrogen. The metal layer 102a, the polysilicon layer 103a, and the silicide layer 104a form a gate electrode 152 of the p-channel MIS transistor. The polysilicon layer 103a contains a p-type impurity.

The p-channel MIS transistor further includes: an insulative protection film 132a formed on the side surfaces of the gate electrode 152; a side wall insulating film 134a formed on the side surfaces of the gate electrode 152, with the protection film 132a interposed therebetween; source/drain regions 130 formed in the n well 105 at both lateral sides of the gate electrode 152, and containing a p-type impurity; extension regions 128 formed in the n well 105 under the protection film 132a and at an inner side of the source/drain region 130, and containing a p-type impurity whose concentration is lower than the concentration of the p-type impurity in the source/drain region 130; and a liner insulating film 150. Further, an isolation insulating film 116 is formed in the n well 115 by a shallow trench isolation (STI) process, etc.

The electric fuse includes: an insulating film 101b formed on the isolation insulating film 116; a metal layer (a second metal containing layer) 102b formed on the insulating film 101b and made, for example, of TiN; a polysilicon layer 103b formed on the metal layer 102b; and a silicide layer 104b formed on the polysilicon layer 103b.

The insulating film 101b is made of the same material as the gate insulating film 101a, has the same thickness as the gate insulating film 101a, and contains, for example, a high-k material. The metal layer 102b is made of the same material as the metal layer 102a, such as TiN, and has the same thickness as the metal layer 102a. The polysilicon layer 103b has almost the same thickness as the polysilicon layer 103a, but the p-type impurity concentration of the polysilicon layer 103b is lower than that of the polysilicon layer 103a. The polysilicon layer 103b does not substantially contain a p-type impurity. The silicide layer 104b is made of the same material as the silicide layer 104a, and has almost the same thickness as the silicide layer 104a.

The electric fuse further includes: a protection film 132b formed on the side surfaces of the metal layer 102b, the polysilicon layer 103b, and the silicide layer 104b; and a side wall insulating film 134b formed on the side surfaces of the metal layer 102b, the polysilicon layer 103b, and the silicide layer 104b, with the protection film 132b interposed between the side surfaces and the side wall insulating film 134b; and the liner insulating film 150. Each of the polysilicon layer 103b and the silicide layer 104b of the electric fuse has a portion of which the width is smaller than the width of the other portion when viewed from above the substrate. This reduced-width portion is a melting portion.

FIG. 10 is a plan view of the electric fuse viewed from above the substrate. The electric fuse is electrically connected to a power supply or a transistor for melting. To provide a low connection resistance, the electric fuse includes a contact region 1001 for electric fuse which is closer to the power supply, and a contact region 1003 for electric fuse which is closer to the transistor for melting. These regions occupy a large area independently of the electric fuse 1002 which is actually melted. Since the electric fuse region 1002 is designed to have a shape appropriate for melting, the width of the electric fuse 1002 is smaller than the widths of the contact regions 1001 and 1003.

If a current flows in the electric fuse in an amount over the limit during the operation of the semiconductor device, the silicide layer (specifically, the melting portion of the silicide layer) will be melted by the heat generated due to resistance. After melting, the current only flows in the metal layer 102b and the polysilicon layer 103b, and therefore, the electrical resistance is significantly increased, compared to before melting. The difference of the electrical resistance can be read by various techniques. For example, the difference of the electrical resistance can be detected using a reference resistance element and a differential amplifier circuit.

FIG. 2 shows an example read circuit for the electric fuse.

In this circuit, a power supply voltage VDD is applied to one end of the electric fuse 201, and a first terminal (drain) of a read pass transistor 203 is connected to the other end of the electric fuse 201. A second terminal (source) of the read pass transistor 203 is connected to ground, and the gate electrode is connected to a read terminal.

Further, a power supply voltage VDD is applied to one end of the reference resistance element 202, and a first terminal (drain) of a read pass transistor 204 is connected to the other end of the reference resistance element 202. A second terminal (source) of the read pass transistor 204 is connected to ground, and the gate electrode is connected to a read terminal.

The node between the electric fuse 201 and the read pass transistor 203 is connected to a first input terminal of a differential amplifier circuit 205. The node between the reference resistance element 202 and the read pass transistor 204 is connected to a second input terminal of the differential amplifier circuit 205.

In this read circuit, an electric potential Va is created between the electric fuse 201 and the read pass transistor 203, and an electric potential Vb is created between the reference resistance element 202 and the read pass transistor 204, when a read signal applied to the read terminal is at a high level. The electric potentials Va and Vb are input to the differential amplifier circuit 205. Thus, the difference between the resistance value of the electric fuse 201 and the resistance value of the reference resistance element 202 is converted to a voltage by the differential amplifier circuit 205, and by detecting this change, the state of the electric fuse 201 can be detected. The resistance value of the electric fuse of the present embodiment significantly varies before and after the electric fuse is melted, and therefore, it is not necessary to increase the size of the differential amplifier circuit 205.

Next, a method for fabricating the semiconductor device of the present embodiment will be described.

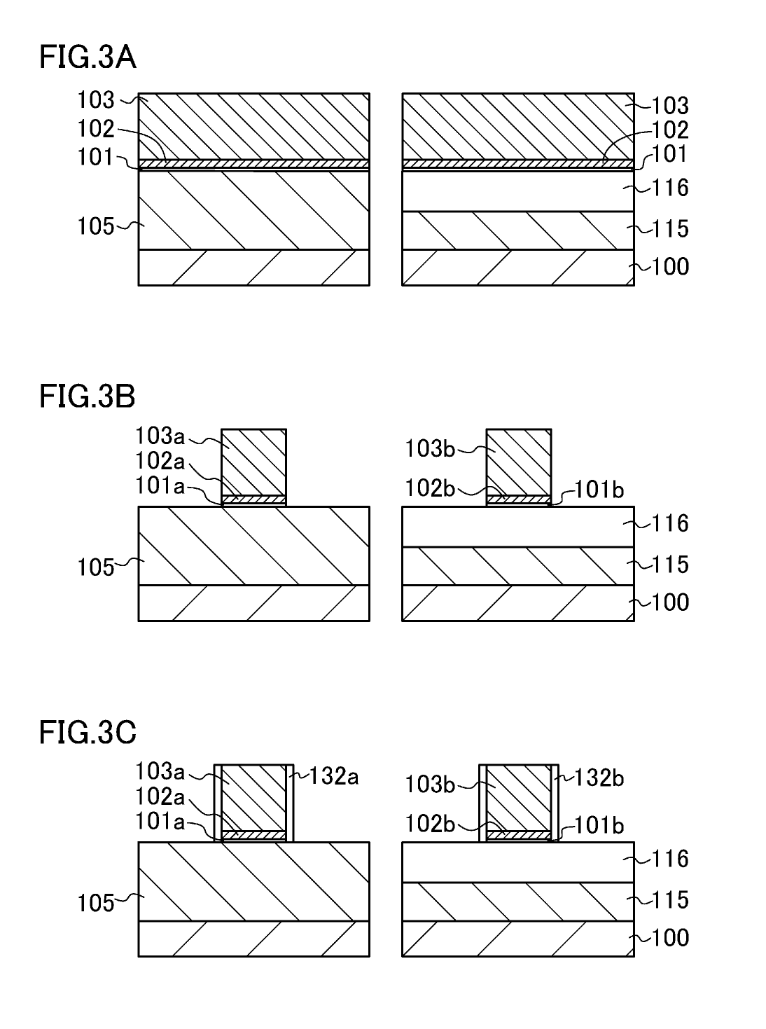

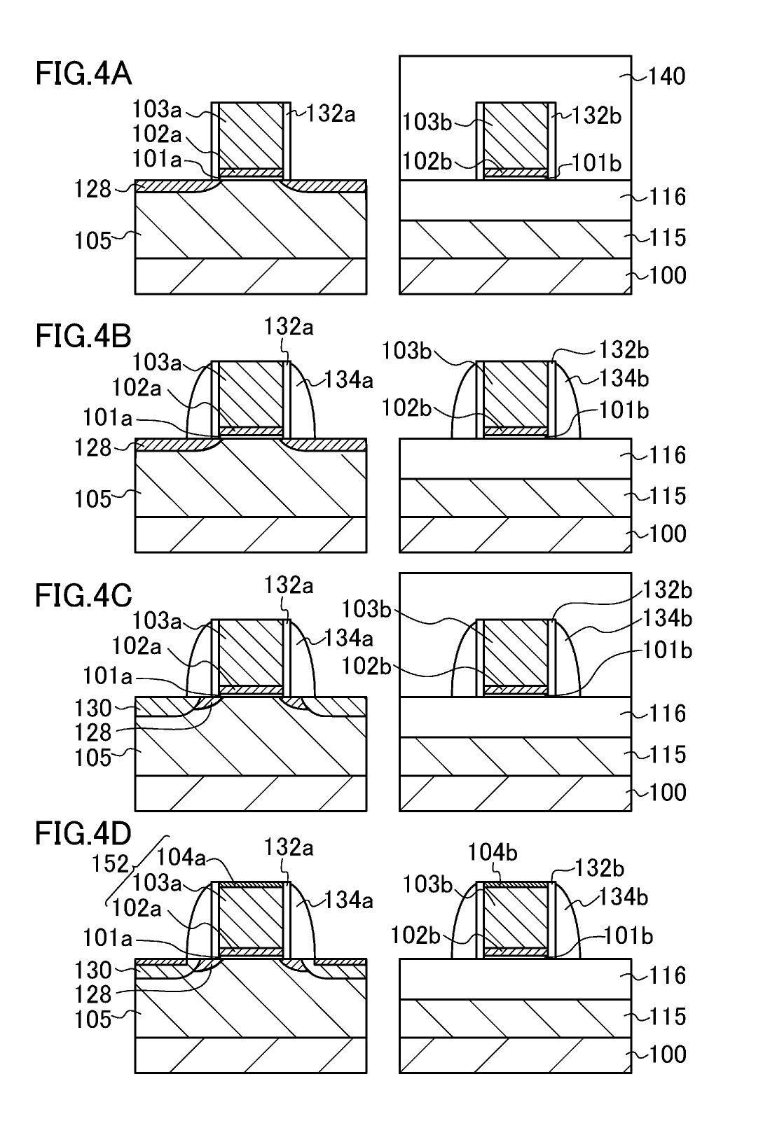

FIGS. 3A-3C and FIGS. 4A-4D are cross-sectional views for showing a method for fabricating a semiconductor device of the present embodiment. The left drawing of each of FIGS. 3A-3C and FIGS. 4A-4D shows a PMIS transistor formation area 121, and the right drawing shows an electric fuse formation area 122.

First, as shown in FIG. 3A, an n well 105 is formed in the PMIS transistor formation area 121 of a semiconductor substrate 100 made, for example, of p-type silicon, and an n well 115 is formed in the electric fuse formation area 122. An isolation insulating film 116 is formed in an upper portion of the semiconductor substrate 100 by an STI process. An electric fuse is formed on the isolation insulating film 116 which is a silicon oxide film.

Then, an insulating film 101 is formed on the upper surface of the isolation insulating film 116 above the semiconductor substrate 100, and thereafter, a TiN layer 102 as a first gate electrode film is deposited on the entire substrate surface (on the insulating film 101) by Ti sputtering in a nitrogen atmosphere to have a thickness of about 5-20 nm. Next, a polysilicon layer 103 as a second gate electrode film is deposited on the entire substrate surface (on the TiN layer 102) by low pressure chemical vapor deposition (LP-CVD) to have a thickness of about 50-120 nm. The polysilicon layer 103 is, for example, an undoped silicon film which is intentionally undoped with an impurity. The undoped silicon film has a high sheet resistance value, i.e., 1000 KΩ/□ or more, even after a heat treatment process, and is therefore suitable as an electric fuse.

Next, as shown in FIG. 3B, the polysilicon layer 103 and the TiN layer 102 are selectively etched by photolithography, thereby forming a gate insulating film 101a, a metal layer 102a, and a polysilicon layer 103a on the n well 105, and forming an insulating film 101b, a metal layer 102b, and a polysilicon layer 103b on the isolation insulating film 116.

Then, as shown in FIG. 3C, an insulating film (e.g., a silicon oxide film having a thickness of 5-10 nm) is deposited on the entire substrate surface by CVD, and thereafter, anisotropic dry etching is performed to form a protection film 132a on the side surfaces of the metal layer 102a and the polysilicon layer 103a, and a protection film 132b on the side surfaces of the metal layer 102b and the polysilicon layer 103b.

Next, as shown in FIG. 4A, p-type impurity ions are implanted using a photoresist 140 which covers at least an upper portion of the electric fuse formation area as a mask to form extension regions 128 in the n well 105 at both lateral sides of the metal layer 102a and the polysilicon layer 103a and under the protection film 132a. The p-type impurity is simultaneously implanted in the polysilicon layer 103a as well. On the other hand, the p-type impurity is not implanted in the polysilicon layer 103b since the polysilicon layer 103b forming the electric fuse is covered with the photoresist 140, and therefore, it is possible to maintain high resistance.

Next, as shown in FIG. 4B, the photoresist 140 is removed and an insulating film (e.g., a silicon nitride film having a thickness of 20-40 nm) is deposited on the entire substrate surface by CVD. After that, anisotropic dry etching is performed to form a side wall insulating film 134a on the protection film 132a, and a side wall insulating film 134b on the protection film 132b.

Then, as shown in FIG. 4C, p-type impurity ions are implanted in the PMIS transistor formation area 121 of the semiconductor substrate 100 using a photoresist formed so as to cover at least the electric fuse formation area as a mask to form source/drain regions 130. The p-type impurity is simultaneously implanted in the polysilicon layer 103a as well. On the other hand, the impurity is not implanted in the polysilicon layer 103b since the polysilicon layer 103b forming the electric fuse is covered with the photoresist, and therefore, it is possible to maintain high resistance. In other words, it is possible to obtain a polysilicon layer whose sheet resistance is 1000 kΩ/□ or more if the polysilicon layer is not doped.

In the present embodiment, no impurity is implanted in the polysilicon layer 103b forming the electric fuse, but an n-type impurity ion such as arsenic (As) and phosphorus (P), a p-type impurity ion such as boron (B) and indium (In), or both of the p-type and n-type impurity ions may be implanted in the polysilicon layer 103b. In this case, as well, the resistance value is increased due to melting of the silicide film, and therefore it is possible to serve as an electric fuse. Even if the polysilicon layer 103a forming the gate electrode of the transistor is doped in a high concentration, the sheet resistance of the polysilicon layer 103b forming the electric fuse is controlled by the above method, and therefore it is possible to obtain different sheet resistance ratios between the case where the silicide layer is melted and the case where the silicide layer is not melted.

In the case where the resistance value of the polysilicon layer 103b is further reduced so that the polysilicon layer 103b can be used as wiring, the sheet resistance can be 30-100Ω/□ or so by implanting impurity ions in the concentration of 1×10²⁰/cm³ or more. In general, it is preferable that the ratio between the sheet resistance of the polysilicon layer 103b of the electric fuse and the sheet resistance of the polysilicon layer 103a of the transistor gate is large, but the ratio may not necessarily be large and selected as appropriate depending on circuit configuration.

Next, a metal layer made, for example, of nickel (Ni) and having a thickness of about 10 nm is deposited on the entire substrate by sputtering. Materials for this metal layer include, for example, cobalt (Co), Ti, and platinum (Pt) or compounds of these materials. The thickness of the metal layer may be 5-15 nm or so. Then, as shown in FIG. 4D, part of the metal layer is silicided by heat treatment, and unreacted metal material is removed to form a silicide layer 104a on the polysilicon layer 103a of the transistor, and a silicide layer 104b on the polysilicon layer 103b of the electric fuse. A silicide layer is formed on the source/drain region 130 as well.

In the present embodiment, the sheet resistances of the silicide layers 104a and 104b can be set to about 10Ω/□ or less. On the other hand, in the case where the resistance value of the polysilicon layer 103b is high (i.e., undoped), the sheet resistance of the metal gate relies almost on the sheet resistance of the metal film, that is about 30Ω/□. Therefore, the resistance value of the electric fuse having a multilayer structure of the metal layer 102b, polysilicon layer 103b, and the silicide layer 104b is approximately quadrupled when the fuse is cut. Even if the resistance value of the polysilicon layer 103b is small (e.g., 30Ω/□ or so), the resistance value is about two and a half times or more when the fuse is cut. Therefore, in either case, the area of the differential amplifier circuit does not need to be significantly changed.

According to the fabrication method of the present embodiment, the polysilicon layer 103a forming the gate electrode of a transistor, and the polysilicon layer 103b forming an electric fuse can have different impurity concentrations, while being simultaneously formed. Thus, the electric fuse can have a high resistance value even after melting, and the difference between the resistance values of the electric fuse before and after the melting can be increased, without an increase in fabrication cost.

According to the semiconductor device and the method for fabricating the semiconductor device of the present embodiment, the metal layer 102b of the electric fuse, and the metal layer 102a forming the gate electrode of the p-channel MIS transistor are made of the same material, i.e., TiN. In the case of using an n-channel MIS transistor and a p-channel MIS transistor whose respective metal layers are made of different materials, the difference between the resistance values of the electric fuse before and after the melting of the silicide layer 104b of the electric fuse can be significantly increased by making the metal layer of the electric fuse have the same structure as the structure of one of the metal layers which has a higher resistance value.

According to the above fabrication method, the structure of the electric fuse is similar to the structure of the gate electrode of the p-channel MIS transistor. Thus, the number of processes is not increased.

According to the semiconductor device of the present embodiment, the time necessary for program can be reduced, while maintaining the resistance value of the electric fuse high after program. It is also possible to decrease a voltage necessary for program, thereby making it possible to cut the fuse without using a power supply voltage supplied from an independent power supply terminal via a smallest transistor used in a system LSI.

According to the semiconductor device of the present embodiment, the structures of the insulating film 101b, the metal layer 102b, the polysilicon layer 103b, the silicide layer 104b, the protection film 132b, the side wall insulating film 134b are similar to the structures of the corresponding elements of the p-channel MIS transistor. Thus, the electric fuse can be formed simultaneously with the p-channel MIS transistor, thereby making it possible to reduce an increase in fabrication cost.

The material for the metal layer 102a, 102b may be a metal other than TiN, or a conductive metallic compound. Part of the metal layer 102a, 102b may contain TiN as long as the metal layer 102a, 102b is conductive.

The silicide layer 104a, 104b may contain platinum.

The electric fuse does not necessarily need to be formed on the isolation insulating film 116 because the electric fuse includes the insulating film 101b.

One of the electrodes of the electric fuse may be connected to a logic power supply of a system LSI. Here, the “logic power supply of a system LSI” is defined as a power supply for a logic circuit inside the system LSI. Supplying the applied voltage via the transistor connected to the logic power supply has advantages including: (1) dimensions of the transistor can be reduced, and the circuit area can be significantly reduced; (2) since the electric fuse is connected to the logic power supply, and a lot of power supply interconnects are provided in a chip, there is almost no limitation in placing a circuit of the electric fuse; and (3) the power supply impedance is stably low.

Even if the impurity concentration (i.e., the p-type impurity concentration) in the polysilicon layer 103b is higher than the impurity concentration (i.e., the p-type impurity concentration) in the polysilicon layer 103a, the change in the resistance value before and after the melting of the electric fuse is significant enough to be detected, and no problem occurs.

—First Variation of Embodiment—

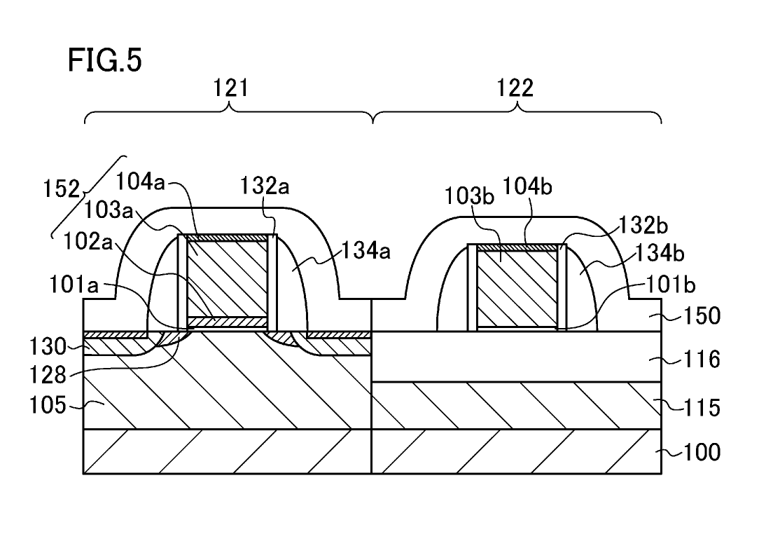

FIG. 5 is a cross-sectional view of a semiconductor device according to the first variation of the embodiment of the present invention. The semiconductor device according to the present variation includes a p-channel MIS transistor and an electric fuse. The semiconductor device according to the present variation is different from the semiconductor device shown in FIG. 1 in that the electric fuse of the present variation does not include a metal layer 102b. The other elements are similar to those of the semiconductor device shown in FIG. 1. Thus, in FIG. 5, like reference characters are used to designate the elements identical to the elements shown in FIG. 1, and the explanation thereof is simplified or omitted.

As described above, in the semiconductor device according to the present variation, the electric fuse includes an insulating film 101b, a polysilicon layer 103b formed on the insulating film 101b, a silicide layer 104b formed on the polysilicon layer 103b, a protection film 132b, and a side wall insulating film 134b.

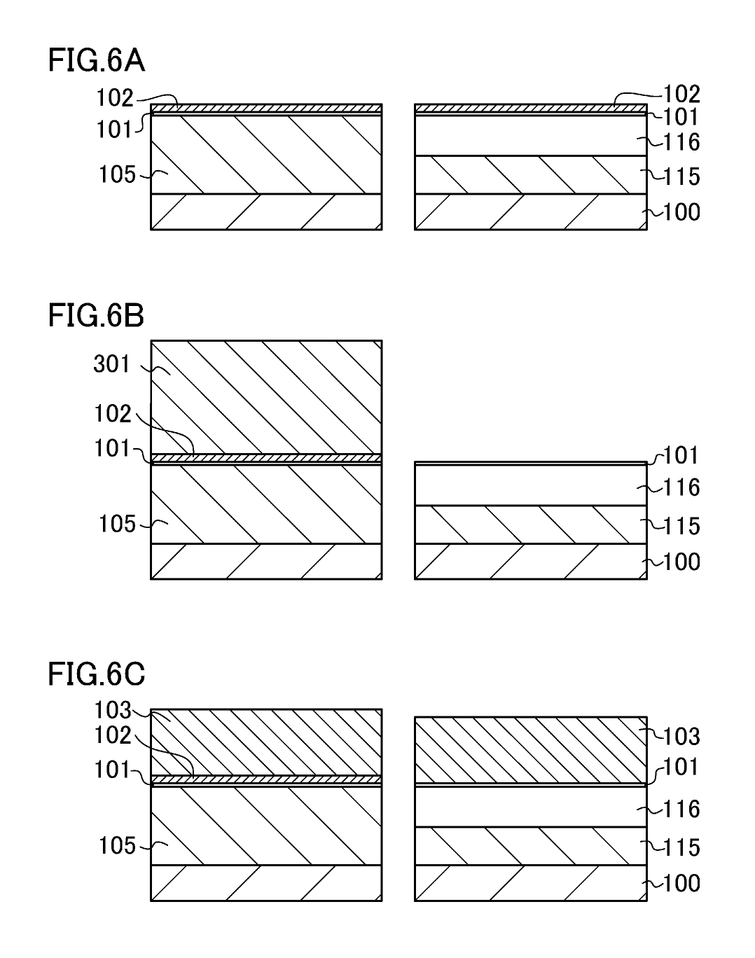

Now, a method for fabricating the semiconductor device according to the present variation will be described. FIGS. 6A-6C, FIGS. 7A-7C, and FIGS. 8A-8C are cross-sectional views for showing a method for fabricating the semiconductor device according to the present variation. The left drawing of each of FIGS. 6A-6C, FIGS. 7A-7C, and FIGS. 8A-8C shows a PMIS transistor formation area 121, and the right drawing shows an electric fuse formation area 122.

First, as shown in FIG. 6A, an n well 105 is formed in the PMIS transistor formation area 121 of the semiconductor substrate 100 made, for example, of p-type silicon, and an n well 115 is formed in the electric fuse formation area 122. An isolation insulating film 116 is formed in an upper portion of the semiconductor substrate 100 by an STI process. The electric fuse is formed on the isolation insulating film 116 which is a silicon oxide film.

Then, an insulating film 101 is formed on the upper surface of the isolation insulating film 116 above the semiconductor substrate 100, and thereafter, a TiN layer 102 as a first gate electrode film is deposited on the entire substrate (on the insulating film 101) by CVD to have a thickness of about 5-20 nm.

Next, as shown in FIG. 6B, the TiN layer 102 is selectively removed with a sulfuric acid-hydrogen peroxide mixture (SPM) using a resist 301 which is formed on the substrate so as to cover at least the area other than the electric fuse formation area, as a mask.

Then, as shown in FIG. 6C, the resist 301 is removed and a polysilicon layer 103 as a second gate electrode film is deposited on the entire substrate surface by LP-CVD to have a thickness of about 50-120 nm. The polysilicon layer 103 is, for example, an undoped silicon film which is intentionally undoped with an impurity. The undoped silicon film has a high resistance value, i.e., 1000 KΩ/□ or more, even after a heat treatment process, and is therefore suitable as an electric fuse.

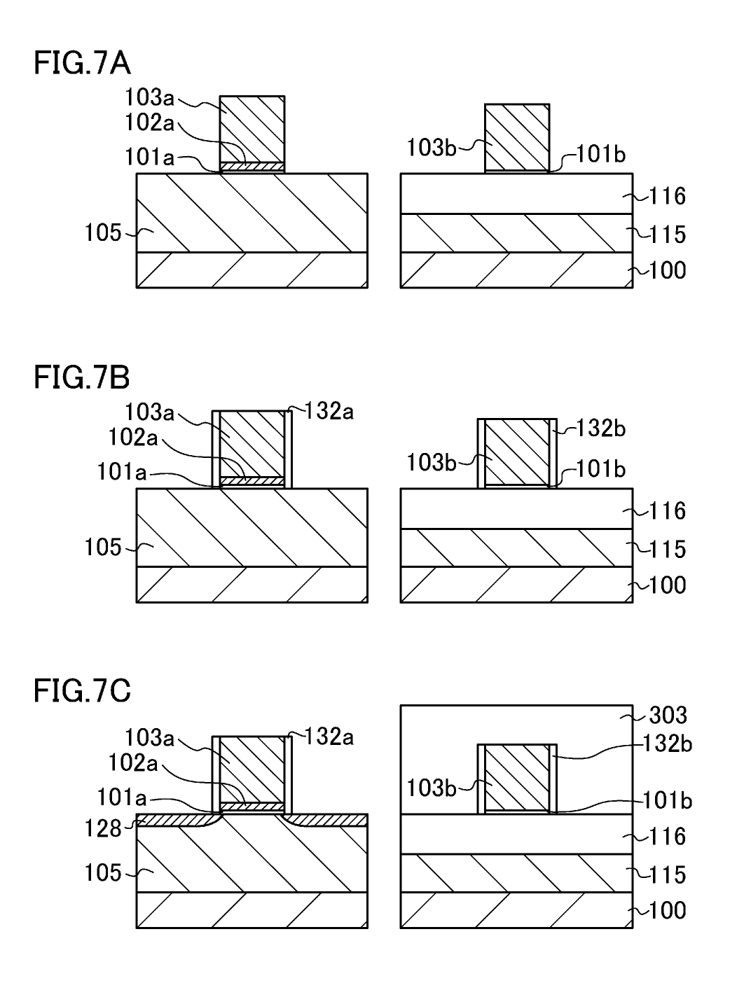

Next, as shown in FIG. 7A, the polysilicon layer 103 and the TiN layer 102 are selectively etched by photolithography, thereby forming a gate insulating film 101a, a metal layer 102a, and a polysilicon layer 103a on the n well 105, and forming an insulating film 101b and a polysilicon layer 103b on the isolation insulating film 116. During the etching of the TiN layer 102, the insulating film 101 on the electric fuse formation area is overetched. As a result, the thickness of the insulating film 101 is reduced, and the upper surface of the isolation insulating film 116 may sometimes be exposed, but there is no impact on the fuse characteristics.

Next, as shown in FIG. 7B, an insulating film (e.g., a silicon oxide film having a thickness of 5-10 nm) is deposited on the entire substrate by CVD, and thereafter, anisotropic dry etching is performed to form a protection film 132a on the side surfaces of the metal layer 102a and the polysilicon layer 103a, and a protection film 132b on the side surfaces of the polysilicon layer 103b.

Next, as shown in FIG. 7C, p-type impurity ions are implanted using a photoresist 303 which covers at least an upper portion of the electric fuse formation area as a mask to form extension regions 128 in the n well 105 at both lateral sides of the metal layer 102a and the polysilicon layer 103a and under the protection film 132a. The p-type impurity is simultaneously implanted in the polysilicon layer 103a as well. On the other hand, the p-type impurity is not implanted in the polysilicon layer 103b since the polysilicon layer 103b forming the electric fuse is covered with the photoresist 140, and therefore, it is possible to maintain high resistance.

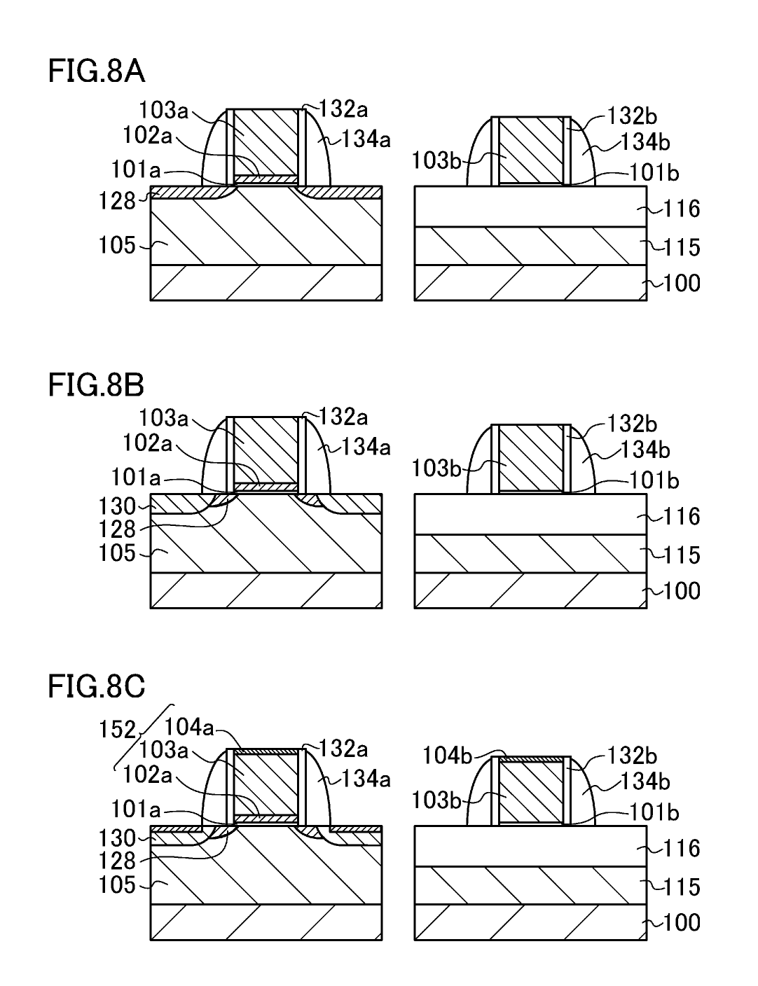

Next, as shown in FIG. 8A, the photoresist 303 is removed and an insulating film (e.g., a silicon nitride film having a thickness of 20-40 nm) is deposited on the entire substrate by CVD. After that, anisotropic dry etching is performed to form a side wall insulating film 134a on the protection film 132a, and a side wall insulating film 134b on the protection film 132b.

Then, as shown in FIG. 8B, p-type impurity ions are implanted in the PMIS transistor formation area 121 of the semiconductor substrate 100 using a photoresist formed so as to cover at least a fuse pattern area as a mask to form source/drain regions 130. The p-type impurity is simultaneously implanted in the polysilicon layer 103a as well. On the other hand, the impurity is not implanted in the polysilicon layer 103b since the polysilicon layer 103b forming the electric fuse is covered with the photoresist, and therefore, it is possible to maintain high resistance. In other words, it is possible to obtain a polysilicon layer whose sheet resistance is 1000 kΩ/□ or more if the polysilicon layer is not doped.

Next, as shown in FIG. 8C, a metal layer made, for example, of nickel (Ni) and having a thickness of about 10 nm is deposited on the entire substrate by sputtering. Materials for this metal layer include, for example, cobalt (Co), Ti, platinum (Pt) or compounds of these materials. The thickness of the metal layer may be 5-15 nm or so. Then, part of the metal layer is silicided by heat treatment, and unreacted metal material is removed to form a silicide layer 104a on the polysilicon layer 103a of the transistor, and a silicide layer 104b on the polysilicon layer 103b of the electric fuse. A silicide layer is formed on the source/drain region 130 as well.

According to the semiconductor device of the present variation, if the silicide layer 104b of the electric fuse is melted, the resistance of the polysilicon layer 103b is the only resistance of the electric fuse. Even if impurity ions are implanted in the polysilicon layer 103b of the electric fuse, melting can make the resistance value of the electric fuse 30-100 times the resistance value before melting, and in the case where the polysilicon layer 103b is undoped, the resistance value after the melting can be 1000 or more times the resistance value before melting. There are cases where the output of the differential amplifier circuit may be more stabilized by allowing a certain amount of current to flow in the fuse even after melting, depending on a circuit configuration guide.

As described above, according to the semiconductor device of the present variation, it is possible to increase the difference between the resistance values of the electric fuse before and after the melting by not providing a metal layer to the electric fuse.

—Second Variation of Embodiment—

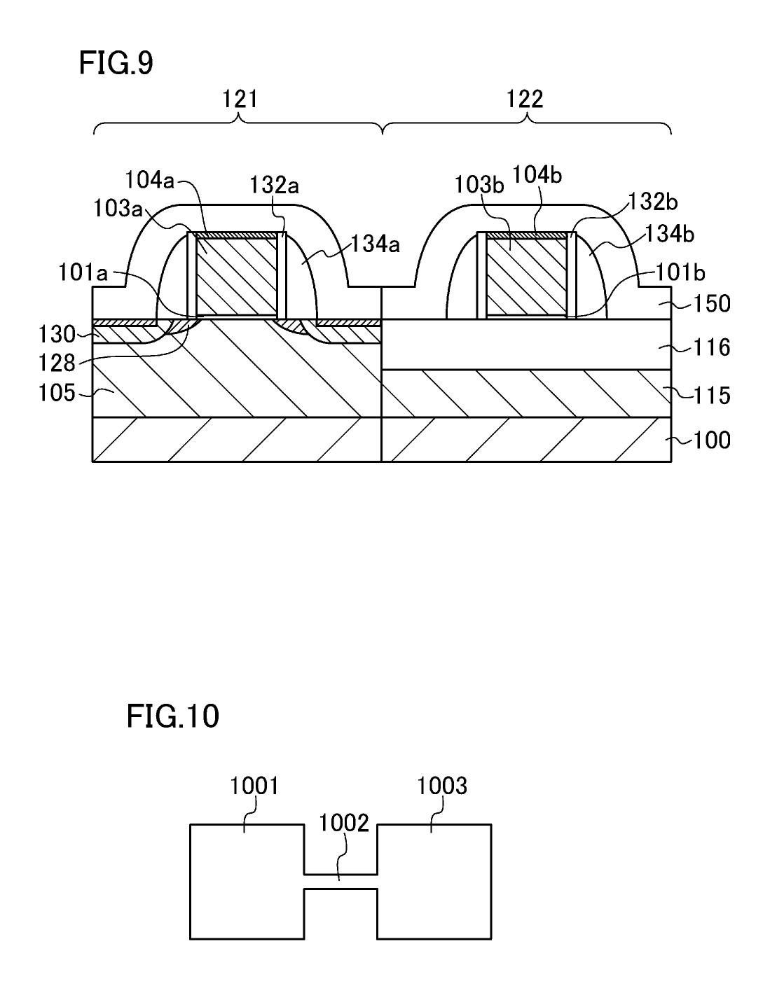

FIG. 9 is a cross-sectional view of a semiconductor device according to the second variation of an embodiment of the present invention. The semiconductor device according to the present variation includes a p-channel MIS transistor and an electric fuse. The semiconductor device according to the present variation is different from the semiconductor device shown in FIG. 5 in that the p-channel MIS transistor of the present variation does not include a metal layer 102a. The gate insulating film 101a and the insulating film 101b may contain a high-k material, or may be made of a silicon oxide film. The other elements are similar to those of the semiconductor device shown in FIG. 5. Thus, in FIG. 9, like reference characters are used to designate the elements identical to the elements shown in FIG. 5, and the explanation thereof is simplified or omitted.

In the semiconductor device according to the present variation, the gate electrode 152 of the p-channel MIS transistor includes a polysilicon layer 103a formed on a gate insulating film 101a and a silicide layer 104a formed on the polysilicon layer 103a.

The electric fuse includes an insulating film 101b, a polysilicon layer 103b formed on the insulating film 101b, a silicide layer 104b formed on the polysilicon layer 103b, a protection film 132b, and a side wall insulating film 134b.

A method of fabricating the semiconductor device according to the present variation is similar to the fabrication method according to the first variation, except that the insulating film 101 is made of a silicon oxide, and that the process of forming the TiN layer 102 is not performed. Specifically, an undoped polysilicon layer 103 is formed by LP-CVD, and thereafter an impurity is implanted in the polysilicon layer 103a, with the polysilicon layer 103b on the electric fuse formation area being covered. Thus, according to the method of the present variation, it is possible to control the impurity concentration in the polysilicon layer 103b which forms the electric fuse. Accordingly, it is possible to significantly reduce the impurity concentration. For example, it is possible to set the sheet resistance of the polysilicon layer 103b to 1000 kΩ/□ or more. Further, since the electric fuse does not include a metal layer, the difference between the resistance values before and after melting can be larger than in the semiconductor device shown in FIG. 1.

In the semiconductor device according to the present variation, no impurity is implanted in the polysilicon layer 103b forming the electric fuse. Alternatively, an n-type impurity ion such as As and P, a p-type impurity ion such as B and In, or both of the n-type and p-type impurity ions may be implanted in the polysilicon layer 103b. In this case, as well, the resistance value is increased due to melting of the silicide film, and therefore it is possible to serve as an electric fuse. Even if the polysilicon layer 103a forming the gate electrode of the transistor is doped in a high concentration, the sheet resistance of the polysilicon layer 103b forming the electric fuse is controlled by the above method, and therefore it is possible to obtain different sheet resistance ratios between the case where the silicide layer is melted and the case where the silicide layer is not melted.

In the case where the resistance value of the polysilicon layer 103b is further reduced so that the polysilicon layer 103b can be used as wiring, the sheet resistance can be 30-100Ω/□ or so by implanting ions in the concentration of 1×10²⁰/cm³ or more. In general, it is preferable that the ratio between the sheet resistance of the polysilicon layer 103b of the electric fuse and the sheet resistance of the polysilicon layer 103a of the transistor gate is large, but the ratio may not necessarily be large and selected as appropriate depending on circuit configuration.

The semiconductor devices described above are example embodiments, and the materials, the thickness, the impurity concentration, and the like of each element can be modified within the scope of the present invention. For example, the structure of the electric fuse may be the same as the structure of the gate electrode of the n-channel MIS transistor.

As described above, the present invention is applicable to a system LSI including a processor, a memory, a PLL circuit, etc., in a leading process in which progress is being made for further miniaturization.

What is claimed is:

1. A semiconductor device comprising:
an MIS transistor formed on a semiconductor substrate; and
an electric fuse formed on the semiconductor substrate, wherein
the MIS transistor includes
a gate insulating film formed on the semiconductor substrate, and
a gate electrode including a first polysilicon layer formed above the gate insulating film, a first silicide layer formed on the first polysilicon layer, and a first metal containing layer formed between the gate insulating film and the first polysilicon layer, and made of a metal or a conductive metallic compound, and
the electric fuse includes
an insulating film formed on the semiconductor substrate,
a second polysilicon layer formed over the insulating film, and
a second silicide layer formed on the second polysilicon layer.

2. A semiconductor device comprising:
an MIS transistor formed on a semiconductor substrate; and
an electric fuse formed on the semiconductor substrate, wherein
the MIS transistor includes
a gate insulating film formed on the semiconductor substrate, and
a gate electrode including a first polysilicon layer formed over the gate insulating film, and a first silicide layer formed on the first polysilicon layer, and
the electric fuse includes
an insulating film formed on the semiconductor substrate,
a second polysilicon layer formed over the insulating film, and
a second silicide layer formed on the second polysilicon layer, and
the first polysilicon layer and the second polysilicon layer have different impurity concentrations.

3. The semiconductor device of claim 2, wherein
the MIS transistor further includes a first metal containing layer made of a metal or a conductive metallic compound between the gate insulating film and the first polysilicon layer, and
the electric fuse further includes a second metal containing layer made of a metal or a conductive metallic compound between the insulating film formed on the semiconductor substrate and the second polysilicon layer.

4. The semiconductor device of claim 1, wherein
the second polysilicon layer contains a p-type impurity, and
the electric fuse is located on an N well.

5. The semiconductor device of claim 1, wherein
an impurity concentration of the second polysilicon layer is different from an impurity concentration of the first polysilicon layer.

6. The semiconductor device of claim 1, wherein
an impurity concentration of the second polysilicon layer is lower than an impurity concentration of the first polysilicon layer.

7. The semiconductor device of claim 1, wherein
a sheet resistance of the second polysilicon layer is higher than a sheet resistance of the first polysilicon layer.

8. The semiconductor device of claim 1, wherein
the second polysilicon layer contains substantially no impurity.

9. The semiconductor device of claim 1, wherein
the gate insulating film and the insulating film contain a high-k material.

10. The semiconductor device of claim 9, wherein
the gate insulating film and the insulating film contain a hafnium oxide.

11. The semiconductor device of claim 1, wherein
the first metal containing layer contains TiN.

12. The semiconductor device of claim 1, wherein
the second silicide layer has a melting portion capable of being melted by a current,
the electric fuse has two electrodes with the melting portion interposed between the two electrodes, and
one of the two electrodes of the electric fuse is connected to a logic power supply of a system LSI.

13. The semiconductor device of claim 12, wherein
the electric fuse includes at least a contact region whose one terminal is connected to the logic power supply of the system LSI, and the melting portion whose width is smaller than a width of the contact region and appropriate for melting.

14. The semiconductor device of claim 1, wherein
the first polysilicon layer and the second polysilicon layer are made of a same material, and having almost a same thickness.

15. The semiconductor device of claim 1, wherein
the first silicide layer and the second silicide layer contain platinum as a silicide material.

16. The semiconductor device of claim 1, wherein
a sheet resistance of the second polysilicon layer included in the electric fuse is 1000 or more times a sheet resistance of the first polysilicon layer forming the gate electrode of the MIS transistor.

17. A method for fabricating a semiconductor device, comprising:
(a) forming a gate insulating film and a first polysilicon layer on a transistor formation area of a semiconductor substrate, and a first insulating film and a second polysilicon layer on an electric fuse formation area of the semiconductor substrate;
(b) implanting an impurity ion in the first polysilicon layer and the transistor formation area of the semiconductor substrate, with the electric fuse formation area on which the second polysilicon layer has been formed covered with a mask; and
(c) forming a first silicide layer on the first polysilicon layer, and a second silicide layer on the second polysilicon layer.

18. The method of claim 17, wherein
the (a) includes
(a1) depositing a second insulating film on the semiconductor substrate,
(a2) depositing an undoped third polysilicon layer over the second insulating film, and
(a3) forming, on the transistor formation area, the gate insulating film which is part of the second insulating film, and the first polysilicon layer which is part of the third polysilicon layer, and forming on the electric fuse formation area, the first insulating film which is part of the second insulating film, and the second polysilicon layer which is part of the third polysilicon layer, by selectively removing part of the second insulating film and the third polysilicon layer.

19. The method of claim 18, wherein
the (a) further includes forming a metal containing film made of a metal or a metallic compound on the second insulating film after the (a1) and before the (a2), and
in the (a3), a first metal containing film is formed between the gate insulating film and the first polysilicon layer, and a second metal containing film is formed between the first insulating film and the second polysilicon layer, by further removing part of the metal containing film.

20. The method of claim 18, wherein
the (a) further includes
forming a metal containing film made of a metal or a metallic compound on the second insulating film after the (a1) and before the (a2), and
removing part of the metal containing film that is formed above the electric fuse formation area, after the forming the metal containing film and before the (a2), and
in the (a3), a first metal containing film is formed between the gate insulating film and the first polysilicon layer by further removing part of the metal containing film.
